(19) United States
(12) Patent Application Publication
(10) Pub. No.: US 2023/0187232 A1
(43) Pub. Date: Jun. 15, 2023

(54) APPARATUS AND METHOD OF TREATING SUBSTRATE

(71) Applicant: SEMES CO., LTD., Cheonan-si (KR)

(72) Inventor: Mu Hyeon LEE, Cheonan-si (KR)

(73) Assignee: SEMES CO., LTD., Cheonan-si (KR)

(21) Appl. No.: 18/056,491

(22) Filed: Nov. 17, 2022

(30) Foreign Application Priority Data
Dec. 14, 2021 (KR) 10-2021-0178483

(51) Int. Cl. H01L 21/67; H01L 21/687; B08B 3/08; B08B 3/02; B08B 3/04; B08B 3/10

(52) U.S. Cl. CPC H01L 21/67051; H01L 21/68764; B08B 3/08; B08B 3/022; B08B 3/041; B08B 3/10; B08B 2203/007

(57) ABSTRACT

Provided is a method of treating a substrate, the method comprising: heating a treatment liquid with a heater unit installed in a circulation line while circulating the treatment liquid in a housing of a tank through the circulation line coupled to the housing to adjust a temperature of the treatment liquid; evaporating water in the treatment liquid in the housing by heating the treatment liquid to a temperature higher than a temperature of water contained in the treatment liquid by the heater unit to adjust a concentration of a chemical liquid contained in the treatment liquid; and supplying the treatment liquid of which the temperature and the concentration are controlled to a substrate to treat the substrate, in which the evaporation of water from the treatment liquid stored in the housing is accelerated by supplying gas to the treatment liquid flowing through the circulation line.

### CROSS-REFERENCE TO RELATED APPLICATIONS

This application claims priority to and the benefit of Korean Patent Application No. 10-2021-0178483 filed in the Korean Intellectual Property Office on Dec. 14, 2021, the entire contents of which are incorporated herein by reference.

### TECHNICAL FIELD

The present invention relates to a substrate treating method and a substrate treating apparatus, and more particularly, to a substrate treating apparatus for treating a substrate by supplying a treatment liquid of which a temperature and a concentration are adjusted to the substrate.

### BACKGROUND ART

A semiconductor process includes a process of cleaning a thin film, foreign substances, particles, and the like on a substrate. These processes are performed by placing the substrate on a spin head so that a pattern side faces up or down, supplying a treatment liquid to the substrate while rotating the spin head, and then drying the wafer.

Recently, a high-temperature liquid, such as an aqueous phosphoric acid solution, is used as a treatment liquid. For example, an aqueous solution of phosphoric acid includes phosphoric acid and water. The liquid supply unit has a supply tank, a liquid supply line, and a nozzle. The supply tank is adjusted so that the temperature of the aqueous phosphoric acid solution and the concentration of phosphoric acid meet the process conditions. For example, the temperature of the aqueous phosphoric acid solution supplied to the substrate may be about 150° C. to 180° C., and the concentration of phosphoric acid in the aqueous phosphoric acid solution may be about 85% to 95%. The aqueous phosphoric acid solution with the adjusted concentration and temperature is supplied from the supply tank to the nozzle through the liquid supply line.

FIG. 1 is a diagram schematically illustrating an example of a supply tank 900. Referring to FIG. 1, the supply tank 900 has a housing 920 and a circulation line 940. In addition, the housing 920 is connected with a liquid inlet line 960 through which a liquid is supplied to the housing 920 from the outside, a waste liquid discharge line 950 for discharging a waste liquid in the housing 920, and a vent line 970 for exhausting water vapor evaporated in the housing 920.

A pump 942 and a heater 944 are installed in the circulation line 940. An aqueous phosphoric acid solution in the housing 920 is heated by the heater 944 while flowing along the circulation line 940. The temperature of the aqueous phosphoric acid solution is adjusted to a set temperature by heating by the heater 944. In addition, the concentration of phosphoric acid in the aqueous phosphoric acid solution is adjusted by evaporating water by heating by the heater 944.

Evaporation of water in the aqueous phosphoric acid solution is mainly performed within the housing 920. Since the aqueous phosphoric acid solution stored in the housing 920 is heated to a temperature higher than the boiling point of water, water evaporates from the water surface of the aqueous phosphoric acid solution, and when the pressure in the housing 920 is increased by evaporation of water, water vapor is discharged through the vent line 970.

However, as described above, although the evaporation of water is performed only at the water surface of the aqueous phosphoric acid solution, it takes a long time for the concentration of phosphoric acid in the aqueous phosphoric acid solution to be adjusted to the set concentration.

### SUMMARY OF THE INVENTION

The present invention has been made in an effort to provide a substrate treating apparatus and method capable of improving substrate treating efficiency when a substrate is treated by supplying a temperature and concentration-adjusted treatment liquid to a substrate.

The present invention has also been made in an effort to provide a substrate treating apparatus and method capable of reducing the time required for adjusting a concentration of a treatment liquid in a supply tank structure in which the concentration of a treatment liquid is adjusted by evaporation of water.

The object of the present invention is not limited thereto, and other objects not mentioned will be clearly understood by those of ordinary skill in the art from the following description.

An exemplary embodiment of the present invention provides an apparatus for treating a substrate, the apparatus including: a cup providing a treatment space therein; a support unit for supporting a substrate and rotating the substrate in the treatment space; a nozzle for supplying a treatment liquid to the substrate; and a liquid supply unit for supplying the treatment liquid to the nozzle. The liquid supply unit includes a tank for storing the treatment liquid, and the tank includes: a housing having a space for storing the treatment liquid therein; a circulation line coupled to the housing to circulate the treatment liquid in the housing; a heater unit installed in the circulation line to heat the treatment liquid; and a first gas supply line connected to the circulation line to supply first gas into the circulation line.

According to the exemplary embodiment, the first gas supply line may be connected to the circulation line downstream of the heater unit.

According to the exemplary embodiment, the circulation line may include: a first line of which a longitudinal direction is provided in a vertical direction; a second line extending from the first line and connected to the housing so as to be provided upstream from the first line; and a third line extending from the first line and coupled to the housing so as to be provided downstream of the first line, and the first gas supply line may be connected to the third line.

According to the exemplary embodiment, the circulation line may have an outlet located lower than a liquid level of the treatment liquid in the housing.

According to the exemplary embodiment, the first gas may be supplied to the circulation line in a heated state.

According to the exemplary embodiment, the first gas may be supplied to the circulation line at the same temperature as a temperature of the treatment liquid heated by the heater unit in the circulation line.

According to the exemplary embodiment, the first gas may be supplied to the circulation line at a room temperature state.

According to the exemplary embodiment, the liquid supply unit may further include a second gas supply line coupled to the housing so as to supply second gas to the housing.

According to the exemplary embodiment, the second gas supply line may be provided to supply the second gas to a position higher than a liquid level of the treatment liquid stored in the housing.

According to the exemplary embodiment, the second gas may be low-humidity gas.

According to the exemplary embodiment, the treatment liquid may include a chemical liquid and water, and the heater unit may heat the treatment liquid to a temperature higher than a boiling point of water.

According to the exemplary embodiment, the treatment liquid may be an aqueous phosphoric acid solution.

Another exemplary embodiment of the present invention provides an apparatus for treating a substrate, the apparatus including: a cup providing a treatment space therein; a support unit for supporting a substrate and rotating the substrate in the treatment space; a nozzle for supplying a treatment liquid to the substrate; and a liquid supply unit for supplying a treatment liquid of which a concentration and a temperature are controlled to the nozzle, in which the treatment liquid includes a chemical liquid and water, and the liquid supply unit includes: a housing having a space for storing the treatment liquid therein; a circulation line coupled to the housing to circulate the treatment liquid in the housing, and including an outlet located lower than a liquid level of the treatment liquid in the housing; a heater unit installed in the circulation line and for heating the treatment liquid to a temperature higher than a boiling point of the water; and a gas supply line directly connected to the circulation line to supply gas into the circulation line.

According to the exemplary embodiment, the gas supply line may be connected to the circulation line downstream of the heater unit.

According to the exemplary embodiment, a heater for heating the first gas may be installed in the gas supply line.

Still another exemplary embodiment of the present invention provides a method of treating a substrate, the method including: heating a treatment liquid with a heater unit installed in a circulation line while circulating the treatment liquid in a housing of a tank through the circulation line coupled to the housing to adjust a temperature of the treatment liquid; evaporating water in the treatment liquid in the housing by heating the treatment liquid to a temperature higher than a temperature of water contained in the treatment liquid by the heater unit to adjust a concentration of a chemical liquid contained in the treatment liquid; and supplying the treatment liquid of which the temperature and the concentration are controlled to a substrate to treat the substrate, in which the evaporation of water from the treatment liquid stored in the housing is accelerated by supplying gas to the treatment liquid flowing through the circulation line.

According to the exemplary embodiment, the treatment liquid and the gas flowing through the circulation line may be discharged to a position lower than a liquid level of the treatment liquid stored in the housing.

According to the exemplary embodiment, the gas may be supplied to the circulation line in a heated state.

According to the exemplary embodiment, the gas may be supplied to the circulation line at the same temperature as a temperature of the treatment liquid heated by the heater unit.

According to the exemplary embodiment, the treatment liquid may be an aqueous phosphoric acid solution.

According to the exemplary embodiment of the present invention, substrate treatment efficiency may be improved when a substrate is treated by supplying the treatment liquid of which a temperature and a concentration are controlled to the substrate.

According to the exemplary embodiment of the present invention, it is possible to shorten the time required for adjusting the concentration of the treatment liquid in the supply tank structure in which the concentration of the treatment liquid is adjusted by evaporation of water.

The effect of the present invention is not limited to the foregoing effects, and those skilled in the art may clearly understand non-mentioned effects from the present specification and the accompanying drawings.

### BRIEF DESCRIPTION OF THE DRAWINGS

FIG. 1 is a diagram schematically illustrating a structure of a general liquid supply unit.

FIG. 2 is a top plan view schematically illustrating a substrate treating apparatus according to an exemplary embodiment of the present invention.

FIG. 3 is a diagram schematically illustrating an exemplary embodiment of a liquid treating chamber of FIG. 2.

FIG. 4 is a diagram schematically illustrating an example of a liquid supply unit according to an exemplary embodiment of the present invention.

FIG. 5 is a diagram schematically illustrating an example of a heater unit of FIG. 4.

FIG. 6 is a diagram schematically illustrating a flow of an aqueous phosphoric acid solution and gas in the liquid supply unit of FIG. 4.

FIG. 7 is a diagram schematically illustrating another exemplary embodiment of the liquid supply unit of FIG. 4.

FIG. 8 is a diagram schematically illustrating a flow of an aqueous phosphoric acid solution and gas in the liquid supply unit of FIG. 7.

FIGS. 9 and 10 are diagrams schematically illustrating a coupling state of the liquid supply unit and the liquid treating chamber, respectively.

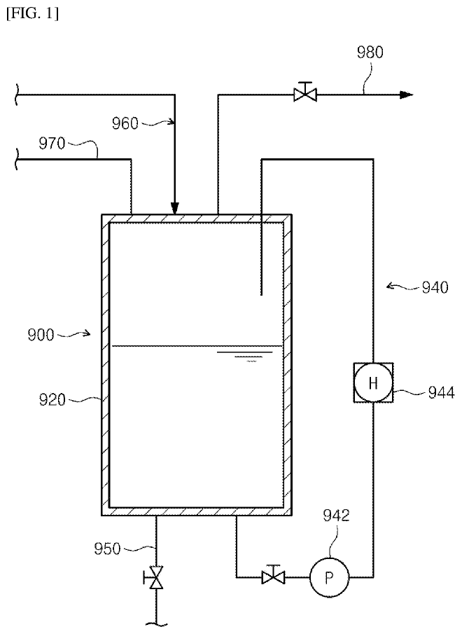

### DETAILED DESCRIPTION

Hereinafter, an exemplary embodiment of the present invention will be described in more detail with reference to the accompanying drawings. The exemplary embodiment of the present invention may be modified in various forms, and the scope of the present invention should not be construed as being limited to the following exemplary embodiments. This exemplary embodiment is provided to more completely explain the present invention to those of ordinary skill in the art. Therefore, the shapes of elements in the drawings are exaggerated to emphasize a clearer description.

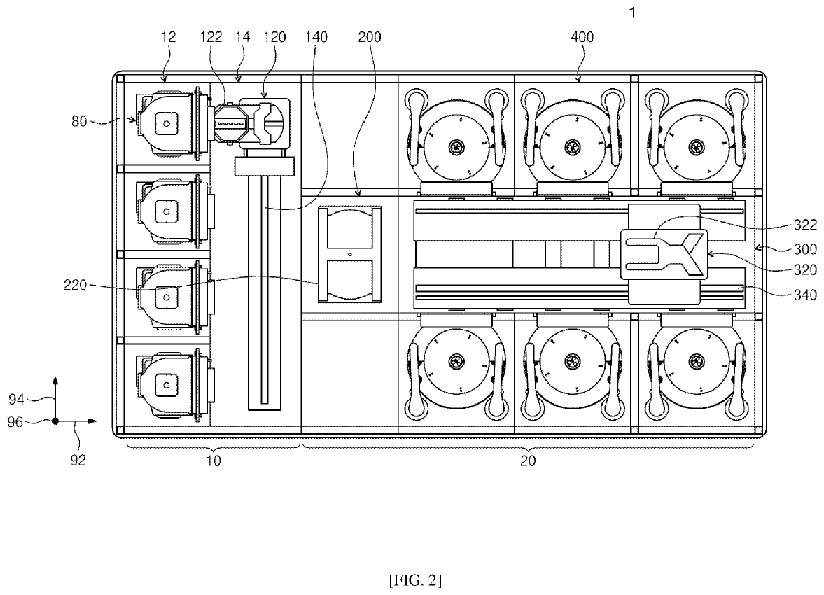

FIG. 2 is a top plan view schematically illustrating a substrate treating apparatus according to an exemplary embodiment of the present invention.

Referring to FIG. 2, a substrate treating apparatus includes an index module 10, a treating module 20, and a controller 30. According to an exemplary embodiment, the index module 10 and the treating module 20 are disposed along one direction. Hereinafter, the direction in which the index module 10 and the treating module 20 are disposed is referred to as a first direction 92, and when viewed from above, a direction vertical to the first direction 92 is referred to as a second direction 94, and a direction vertical to both the first direction 92 and the second direction 94 is referred to as a third direction 96.

The index module 10 transfers a substrate W from a container 80 in which the substrate W is accommodated to the treating module 20, and makes the substrate W, which has been completely treated in the treating module 20, be accommodated in the container 80. A longitudinal direction of the index module 10 is provided in the second direction 94. The index module 10 includes a load port 12 and an index frame 14. Based on the index frame 14, the load port 12 is located at a side opposite to the treating module 20. The container 80 in which the substrates W are accommodated is placed on the load port 12. The load port 12 may be provided in plurality, and the plurality of load ports 12 may be disposed in the second direction 94.

As the container 80, an airtight container, such as a Front Open Unified Pod (FOUP), may be used. The container 80 may be placed on the load port 12 by a transport means (not illustrated), such as an overhead transfer, an overhead conveyor, or an automatic guided vehicle, or an operator.

An index robot 120 is provided to the index frame 14. A guide rail 140 of which a longitudinal is the second direction 94 is provided within the index frame 14, and the index robot 120 may be provided to be movable on the guide rail 140. The index robot 120 includes a hand 122 on which the substrate W is placed, and the hand 122 may be provided to be movable forward and backward, rotatable based on the third direction 96 as an axis, and movable in the third direction 96. A plurality of hands 322 are provided to be spaced apart in the vertical direction, and the hands 322 may move forward and backward independently of each other.

The treating module 20 includes a buffer unit 200, a transfer chamber 300, and a treating chamber 400. The buffer unit 200 provides a space in which the substrate W loaded to the treating module 20 and the substrate W unloaded from the treating module 20 stay temporarily. The treating chamber 400 performs a treatment process of liquid-treating the substrate W by supplying a liquid onto the substrate W. The transfer chamber 300 transfers the substrate W between the buffer unit 200 and the liquid treating chamber 400.

The transfer chamber 300 may be provided so that a longitudinal direction is the first direction 92. The buffer unit 200 may be disposed between the index module 10 and the transfer chamber 300. A plurality of liquid treating chambers 400 is provided and may be disposed on the side of the transfer chamber 300. The liquid treating chamber 400 and the transfer chamber 300 may be disposed in the second direction 94. The buffer unit 220 may be located at one end of the transfer chamber 300.

According to the example, the liquid treating chambers 400 may be disposed at both sides of the transfer chamber 300. At each of both sides of the transfer device 300, the liquid treating chambers 400 may be provided in an array of A×B (each of A and B is 1 or a natural number larger than 1) in the first direction 92 and the third direction 96.

The transfer chamber 300 has a transfer robot 320. A guide rail 340 having a longitudinal direction in the first direction 92 is provided in the transfer chamber 300, and the transfer robot 320 may be provided to be movable on the guide rail 340. The transfer robot 320 includes a hand 322 on which the substrate W is placed, and the hand 322 may be provided to be movable forward and backward, rotatable based on the third direction 96 as an axis, and movable in the third direction 96. A plurality of hands 322 are provided to be spaced apart in the vertical direction, and the hands 322 may move forward and backward independently of each other.

The buffer unit 200 includes a plurality of buffers 220 on which the substrate W is placed. The buffers 220 may be disposed while being spaced apart from each other in the third direction 96. A front face and a rear face of the buffer unit 200 are opened. The front face is a face facing the index module 10, and the rear face is a face facing the transfer chamber 300. The index robot 120 may approach the buffer unit 200 through the front face, and the transfer robot 320 may approach the buffer unit 200 through the rear face.

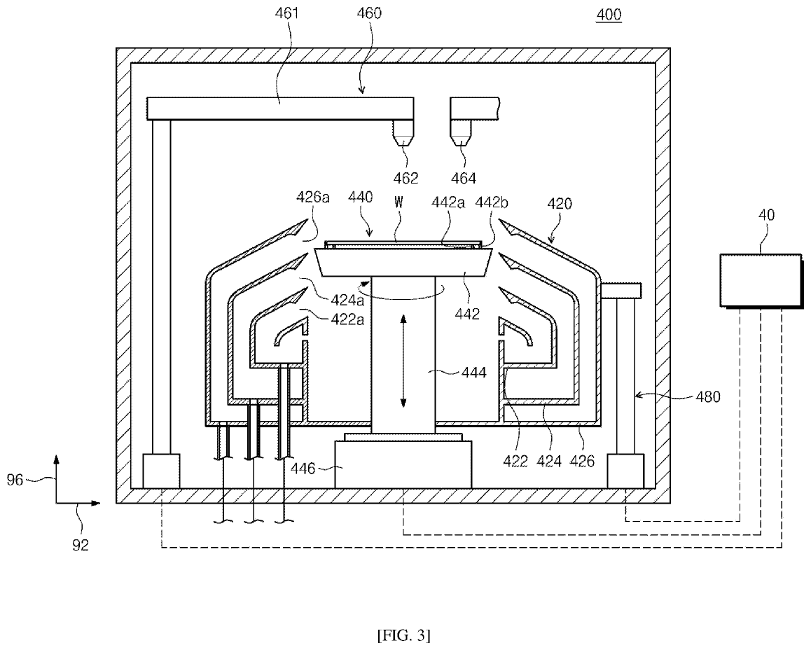

FIG. 3 is a diagram schematically illustrating an exemplary embodiment of the liquid treating chamber 400 of FIG. 2. Referring to FIG. 3, the liquid treating chamber 400 includes a housing 410, a cup 420, a support unit 440, a nozzle unit 460, a lifting unit 480, a supply unit, and a controller.

The housing 410 is provided in a generally rectangular parallelepiped shape. The cup 420, the support unit 440, and the liquid supply unit 460 are disposed in the housing 410.

The cup 420 has a treatment space with an open top, and the substrate W is liquid-treated in the treatment space. The support unit 440 supports the substrate W in the treatment space. The liquid supply unit 460 supplies the liquid onto the substrate W supported by the support unit 440. The liquid may be provided in a plurality of types, and may be sequentially supplied onto the substrate W. The lifting unit 480 adjusts a relative height between the cup 420 and the support unit 440.

According to one example, the cup 420 includes a plurality of recovery containers 422, 424, and 426. Each of the recovery containers 422, 424, and 426 has a recovery space of recovering the liquid used for the treatment of the substrate. Each of the recovery containers 422, 424, and 426 is provided in a ring shape surrounding the support unit 440. When the liquid treatment process is in progress, the treatment liquid scattered by the rotation of the substrate W may be introduced into the recovery space through inlets 422a, 424a, and 426a of the respective recovery containers 422, 424, and 426 to be described later. According to one example, the cup 420 includes the first recovery container 422, the second recovery container 424, and the third recovery container 426. The first recovery container 422 is disposed to surround the support unit 440, the second recovery container 424 is disposed to surround the first recovery container 422, and the third recovery container 426 is disposed to surround the second recovery container 424. The second inlet 424a through which the liquid is introduced to the second recovery container 424 may be located above the first inlet 422a through which the liquid is introduced to the first recovery container 422, and the third inlet 426a through which the liquid is introduced to the third recovery container 426 may be located above the second inlet 424a.

The support unit 440 includes a support plate 442 and a driving shaft 444. An upper surface of the support plate 442 may be provided in a generally circular shape, and may have a diameter larger than a diameter of the substrate W. A support pin 442a supporting the rear surface of the substrate W is provided to a center portion of the support plate 442, and an upper end of the support pin 442a is provided to protrude from the support plate 442 so that the substrate W is spaced apart from the support plate 442 by a predetermined distance. A chuck pin 442b is provided to an edge of the support plate 442. The chuck pin 442b is provided to protrude upward from the support plate 442, and supports the lateral portion of the substrate W so that the substrate W is not separated from the support unit 440 when the substrate W is rotated. The driving shaft 444 is driven by the driver 446, is connected to the center of the bottom surface of the substrate W, and rotates the support plate 442 based on the central axis thereof.

The nozzle unit 460 has a first nozzle 462 and a second nozzle 464. The first nozzle 462 supplies the treatment liquid onto the substrate W. The treatment liquid may be a liquid having a temperature higher than room temperature. According to an example, the treatment liquid may be an aqueous phosphoric acid solution. The aqueous phosphoric acid solution may be a mixture of phosphoric acid and water. Optionally, the aqueous phosphoric acid solution may further contain other substances. For example, the other material may be silicon. The second nozzle 464 supplies water onto the substrate W. The water may be pure water or deionized water.

The first nozzle 462 and the second nozzle 464 are respectively supported on different arms 461, and these arms 461 may be moved independently. Optionally, the first nozzle 462 and the second nozzle 464 may be mounted on the same arm and moved at the same time.

Optionally, the liquid supply unit may further include one or more nozzles in addition to the first nozzle 462 and the second nozzle 464. Additional nozzles may supply different types of treatment liquids to the substrate. For example, the other type of treatment liquid may be an acid solution or a base solution for removing foreign substances on the substrate. In addition, another type of treatment liquid may be alcohol having surface tension lower than that of water. For example, the alcohol may be isopropyl alcohol.

The lifting unit 480 moves the cup 420 in the vertical direction. By the vertical movement of the cup 420, a relative height between the cup 420 and the substrate W is changed. Accordingly, since the recovery containers 422, 424, and 426 for recovering the treatment liquid are changed according to the type of the liquid supplied to the substrate W, the liquids may be separated and collected. Unlike the above, the cup 420 is fixedly installed, and the lifting unit 480 may move the support unit 440 in the vertical direction.

The liquid supply unit 1000 supplies the treatment liquid to the first nozzle 462. Hereinafter, the case in which the treatment liquid is an aqueous phosphoric acid solution will be described as an example.

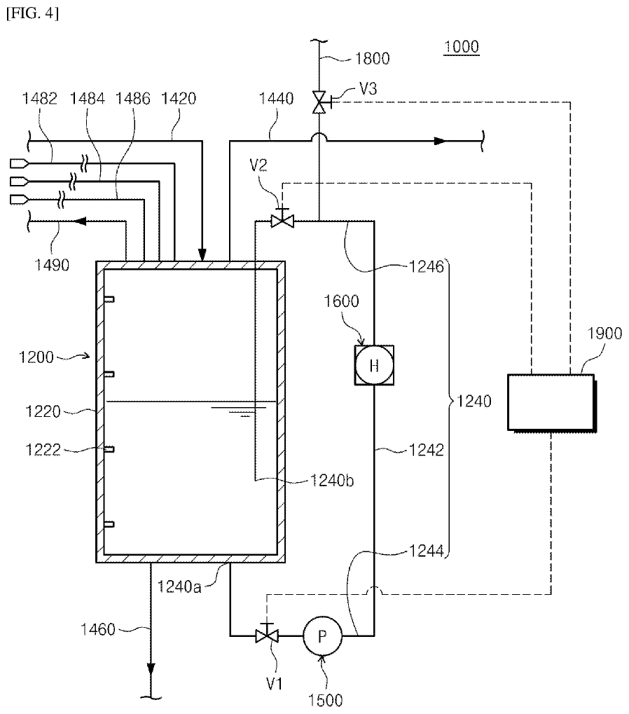

FIG. 4 is a diagram schematically illustrating an example of the liquid supply unit according to the exemplary embodiment of the present invention. Referring to FIG. 4, the liquid supply unit 1000 includes a supply tank 1200. The supply tank 1200 includes a housing 1220 and a circulation line 1240.

The housing 1220 is provided in a rectangular parallelepiped or cylindrical shape. The housing 1220 has a space in which the aqueous phosphoric acid solution is stored.

An inlet line 1420 and an outlet line 1440 are connected to the housing 1220. A valve (not illustrated) is installed in each of the inlet line 1420 and the outlet line 1440. The aqueous phosphoric acid solution is introduced into the housing 1220 through the inlet line 1420. The aqueous phosphoric acid solution may be introduced into the housing 1220 through the inlet line 1420 at a temperature lower than a set temperature used for substrate treatment. In addition, the aqueous phosphoric acid solution may be introduced into the housing 1220 through the inlet line 1420 at a concentration lower than the set concentration of phosphoric acid used for substrate treatment. Optionally, the aqueous phosphoric acid solution is introduced into the housing 1220 through the inlet line 1420 in a state in which the aqueous phosphoric acid solution is controlled to a set temperature and set concentration, and the treatment liquid of which temperature and concentration are adjusted is supplied to the outside from the housing 1220 through the outlet line 1440. Each of the inlet line 1420 and the outlet line 1440 may be coupled to the housing 1220 through an upper wall of the housing 1220.

A waste liquid line 1460 is connected to the housing 1220. A valve (not illustrated) is installed in the waste liquid line 1460. When the aqueous phosphoric acid solution is discarded after being reused a certain number of times or for a certain period of time, the aqueous phosphoric acid solution in the housing 1220 is discharged to the outside of the housing 1220 through the waste liquid line 1460.

A phosphoric acid replenishment line 1482 and a water replenishment line 1484 may be connected to the housing 1220. A valve (not illustrated) is installed in the phosphoric acid replenishment line 1482 and the water replenishment line 1484. The phosphoric acid replenishment line 1482 may replenish phosphoric acid to the aqueous phosphoric acid solution introduced into the housing 1220, and the water replenishment line 1484 may replenish water to the phosphoric acid aqueous solution introduced into the housing 1220. Replenishment of phosphoric acid and water may be made based on the liquid level of the aqueous phosphoric acid solution measured by a liquid level measuring sensor 1222 provided in the housing 1220. Optionally, after the phosphoric acid aqueous solution is reused a certain number of times or for a certain period of time and the phosphoric acid aqueous solution is discharged from the housing 1220, phosphoric acid and water may be replenished. When the phosphoric acid aqueous solution contains silicone, a silicone replenishment line 148 may be further connected.

A vent line 1490 is connected to the housing 1220. The vent line 1490 exhausts water vapor evaporated from the aqueous phosphoric acid solution stored in the housing 1220 to the outside of the housing 1220. The vent line 1490 is coupled to the upper surface of the housing 1220. The vent line 1490 is provided with a smaller diameter than other lines. When an internal pressure of the housing 1220 is greater than or equal to a predetermined pressure, the gas in the housing 1220 may be discharged through the vent line 1490.

In the above-described example, each of the waste liquid line 1460 and the outlet line 1440 are illustrated as being connected to the housing 1220. However, unlike this, the waste liquid line 1460 and the outlet line 1440 may be connected to the circulation line 1240.

A circulation line 1240 is connected to the housing 1220. According to the example, one end of the circulation line 1240 functions as an inlet 1240a and is coupled to the bottom surface of the housing 1220. The other end of the circulation line 1240 functions as an outlet 1240b and is immersed in the aqueous phosphoric acid solution in the housing 1220. Optionally, the other end of the circulation line 1240 may be located higher than the liquid level of the aqueous phosphoric acid solution stored in the housing 1220.

A pump unit 1500 and a heater unit 1600 are mounted on the circulation line 1240. The pump unit 1500 provides a flow pressure that causes the aqueous phosphoric acid solution in the housing 1220 to flow in the circulation line 1240. The heater unit 1600 heats the aqueous phosphoric acid solution flowing in the circulation line 1240. According to the example, the heater unit 1600 is controlled to heat the aqueous phosphoric acid solution to a set temperature. The set temperature may be about 150° C. to 180° C.

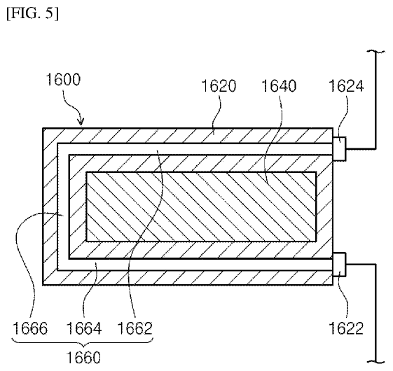

FIG. 5 is a diagram schematically illustrating the heater unit 1600.

Referring to FIG. 5, the heater unit 1600 includes a body 1620 and a heater 1640. The heater 1640 is located inside the body 1620. The body 1620 is provided with a first port 1622 and a second port 1624. The aqueous phosphoric acid solution flows into the heater unit 1600 through the first port 1622 and is discharged to the outside from the heater unit 1600 through the second port 1624. A flow path 1660 through which the aqueous phosphoric acid solution flows is formed in the body 1620. The flow path 1660 is connected to the first port 1622 and the second port 1624. According to the example, the flow path 1660 may include an inflow path 1662, an outlet path 1664, and a connection path. The first port 1622 is located at one end of the inflow path 1662, and the second port 1624 is located at one end of the outlet path 1664. The connection path 1666 connects the inflow path 1662 and the outlet path 1664. The inflow path 1662 and the outlet path 1664 may be provided to face each other. The inflow path 1662 and the outlet path 1664 may be located parallel to each other and spaced apart from each other by a predetermined distance. The heater 1640 may be located in a space surrounded by the inflow path 1662, the outlet path 1664, and the connection path 1666. The structure of the heater unit 1600 is not limited thereto and may be variously changed.

The circulation line 1240 includes a first line 1242, a second line 1244, and a third line 1246. The first line 1242 is located outside the housing 1220. According to the example, the first line 1242 may be located in a substantially vertical direction. The flow path 1660 provided in the heater unit 1600 may be provided as a part of the first line 1242. The second line 1244 includes the inlet 1240a of the circulation line 1240. The second line 1244 extends from the lower end of the first line 1242 and is coupled to the lower surface of the housing 1220. The third line 1246 includes the outlet 1240b of the circulation line 1240. The third line 1246 extends from the upper end of the first line 1242 and is coupled to the housing 1220 through the upper surface of the housing 1220. The outlet 1240b in the third line 1246 may be immersed in the aqueous phosphoric acid solution stored in the housing 1220. A valve V1 may be installed in the second line 1244, and a valve V2 may be installed in the third line 1246.

According to the example, the heater unit 1600 may be installed in the first line 1242, and the pump unit 1500 may be installed in the second line 1244.

The supply tank 1200 is provided with a gas supply line 1800. A gas valve V3 is mounted on the gas supply line 1800. In one example, the gas supply line 1800 is coupled to the circulation line 1240. The gas supply line 1800 introduces gas into the treatment liquid flowing through the circulation line 1240. The gas promotes evaporation of the water contained in the aqueous phosphoric acid solution within the housing 1220.

The gas supply line 1800 may be connected to the circulation line 1240 downstream of the heater unit 1600. The gas supply line 1800 may be connected to the third line 1246. The gas may be air. Alternatively, inert gas, such as nitrogen gas, may be used as the gas. A heater may be installed in the gas supply line 1800. The gas may be supplied to the circulation line 1240 while being heated by the heater. This may minimize a decrease in the temperature of the aqueous phosphoric acid solution when the gas is mixed with the phosphoric acid aqueous solution in the circulation line 1240. According to the example, the gas may be heated by the heater in the circulation line 1240 to the same temperature as that of the aqueous phosphoric acid solution heated by the heater unit 1600. This prevents the temperature of the aqueous phosphoric acid solution from lowering when the gas is mixed with the phosphoric acid aqueous solution in the circulation line 1240.

In FIG. 4, it has been described that the gas supply line 1800 is connected to the first line 1242. However, alternatively, the gas supply line 1800 may be installed at a point where the first line 1242 and the third line 1246 are connected. In this case, the gas supply line 1800 may be connected in a direction toward the third line 1246.

In addition, although not illustrated, a densitometer for measuring the concentration of phosphoric acid in the aqueous phosphoric acid solution and a thermometer for measuring the temperature of the aqueous phosphoric acid solution may be installed in the supply tank 1200. The densitometer and the thermometer may be installed in the housing 1220 or the circulation line 1240.

The valves V1, V2, and V3 installed in the liquid supply unit 1000 are controlled by the controller 1900.

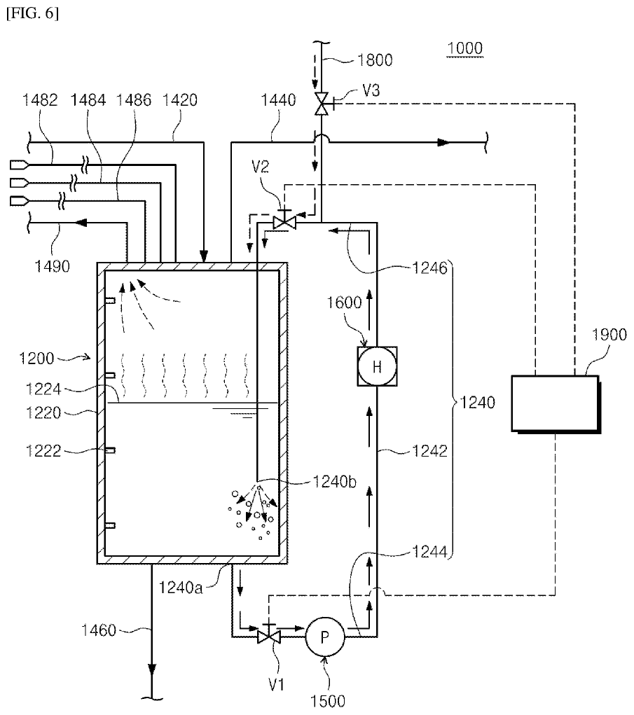

FIG. 6 is a diagram schematically illustrating a state in which the temperature and the concentration of phosphoric acid are adjusted in the supply tank of FIG. 4. In FIG. 5, an arrow indicated by a solid line shows a flow path of the aqueous phosphoric acid solution, and an arrow indicated by a dotted line shows a flow path of gas.

The aqueous phosphoric acid solution is initially supplied into the housing 1220 through the inlet line 1420. The initially supplied phosphoric acid aqueous solution may be at a temperature lower than the process temperature used for the process. For example, the process temperature of the aqueous phosphoric acid solution may be about 150° C. to 180° C., and the phosphoric acid aqueous solution initially supplied into the housing 1220 may be at room temperature. In addition, the process concentration of phosphoric acid in the aqueous phosphoric acid solution may be about 85% to 95%, and the concentration of phosphoric acid in the aqueous phosphoric acid solution initially supplied to the housing 1220 may be about 70% to 80%.

The aqueous phosphoric acid solution supplied into the housing 1220 is circulated through the circulation line 1240 and heated to the process temperature by the heater unit 1600. Then, as the gas valve V3 installed in the gas supply line 1800 is opened, the gas is introduced into the aqueous phosphoric acid solution circulating through the circulation line 1240. Since the outlet 1240b of the circulation line 1240 is located lower than a water surface 1224 of the aqueous phosphoric acid solution stored in the housing 1220, the aqueous phosphoric acid solution mixed with the gas is discharged into the aqueous phosphoric acid solution stored in the housing 1220.

Since the aqueous phosphoric acid solution in the housing 1220 is higher than the boiling point of water, the water evaporates from the aqueous phosphoric acid solution, and as the water evaporates, the concentration of phosphoric acid in the aqueous phosphoric acid solution increases. In general, the evaporation of water within the housing 1220 occurs on the water surface 1224 of the aqueous phosphoric acid solution. However, according to the exemplary embodiment of FIG. 4, since bubbles are mixed in the aqueous phosphoric acid solution discharged from the circulation line 1240, water is also evaporated inside the aqueous phosphoric acid solution stored in the housing 1220. Therefore, the time required to control the concentration of phosphoric acid in the phosphoric acid aqueous solution is shortened.

In addition, when the gas supply line 1800 is installed to pass through the housing 1220 and to be immersed in the aqueous phosphoric acid solution, in order to prevent the aqueous phosphoric acid solution from leaking from the housing 1220, the structure in which the gas supply line 1800 and the housing 1220 are connected is complicated. However, in the present exemplary embodiment, since the gas supply nozzle 1800 is directly connected to the circulation line 1240 from the outside of the housing 1220, the coupling structure is simple.

When the pressure in the housing 1220 increases due to evaporation of water, water vapor and gas in the upper region of the housing 1220 are discharged through the vent line 1400. When the temperature and the concentration of the aqueous phosphoric acid solution are adjusted in the supply tank 1200, the aqueous phosphoric acid solution is supplied to the substrate through the outlet line 1440.

When the liquid level 1224 of the aqueous phosphoric acid solution in the housing 1220 is lower than a set value, phosphoric acid or water may be replenished through the phosphoric acid replenishment 1482 and the water replenishment line 1484.

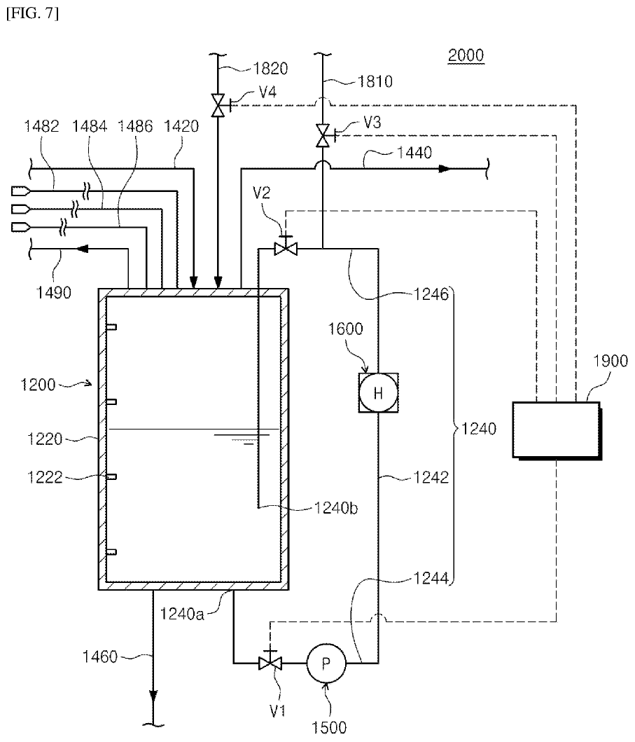

FIG. 7 is a diagram schematically illustrating another exemplary embodiment of the liquid supply unit of FIG. 4. Hereinafter, parts different from the exemplary embodiment of FIG. 4 will be mainly described.

A liquid supply unit 2000 includes a first gas supply line 1810 and a second gas supply line 1820. The first gas supply line 1810 corresponds to the gas supply line 1800 described in the exemplary embodiment of FIG. 4. The second gas supply line 1820 is connected to the housing 1220. The second gas supply line 1820 is coupled to the upper wall of the housing 1200 and supplies second gas to a position higher than the water surface 1224 of the aqueous phosphoric acid solution in the housing 1200. As the second gas, low-humidity gas is used. For example, the second gas may be dry air. The second gas may be supplied at room temperature. Optionally, the second gas may be supplied in a heated state. For example, the second gas may be supplied at the same temperature as that of the aqueous solution of phosphoric acid heated by the heater unit.

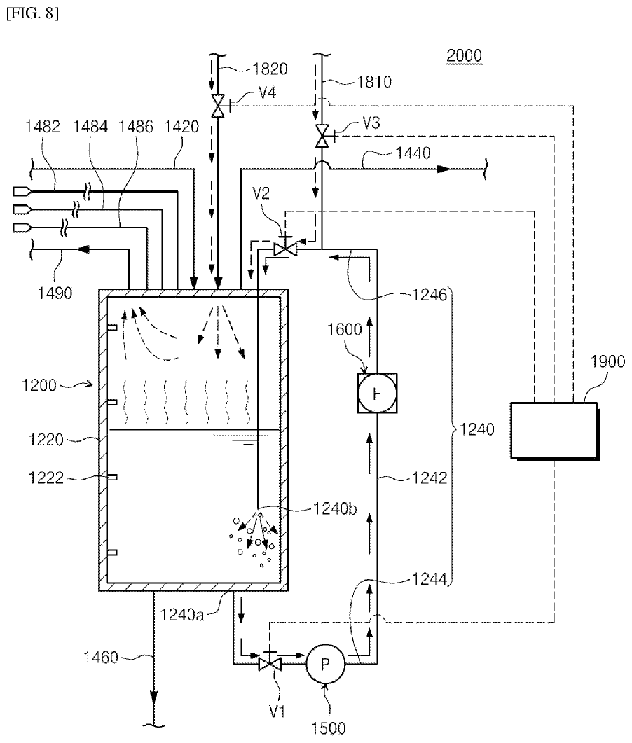

As water evaporates from the aqueous phosphoric acid solution, the humidity in the housing 1220 increases. This prevents the continuous evaporation of water from the aqueous phosphoric acid solution. In the present exemplary embodiment, as illustrated in FIG. 8, the second gas is continuously supplied into the housing 1220 from the second gas supply line 1820 while the aqueous phosphoric acid solution is circulated through the circulation line 1240. Thereby, the humidity in the housing 1220 is lowered, and evaporation of water in the aqueous phosphoric acid solution is promoted.

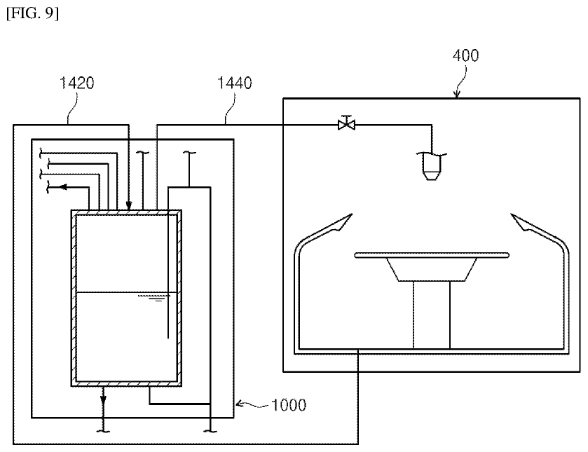

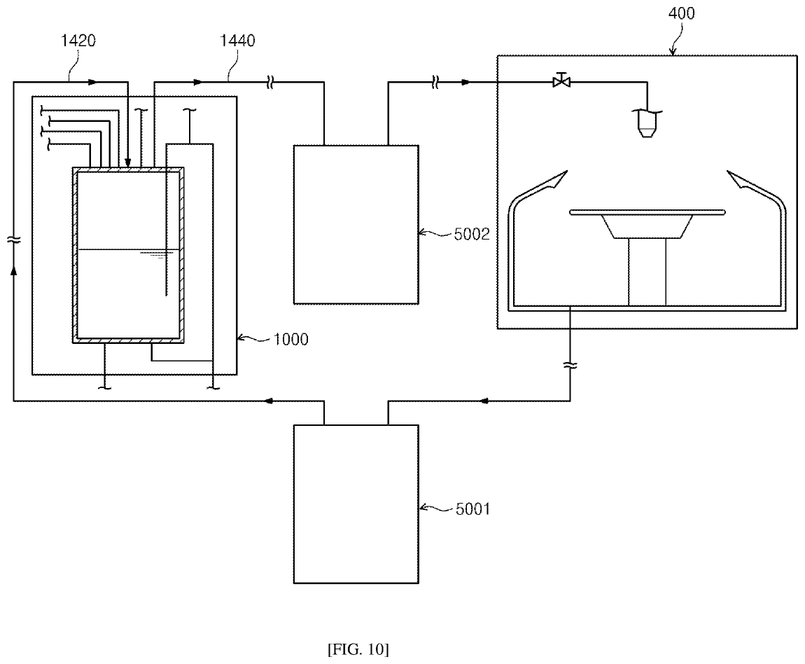

FIGS. 9 and 10 are diagrams schematically illustrating a coupling state of the liquid supply unit and the liquid treating chamber, respectively.

As illustrated in FIG. 9, the inlet line 1420 connected to the housing 1220 of the supply tank 1200 may be directly coupled to the liquid treating chamber 400. In this case, the treatment liquid used for substrate treatment in the liquid treating chamber 400 is directly recovered to the housing 1220 of the supply tank 1200. Also, the outlet line 1440 may be directly coupled to a nozzle of the liquid treatment chamber 400. In this case, the phosphoric acid aqueous solution of which the temperature and the concentration are controlled in the supply tank 1200 is directly supplied to the nozzle of the liquid treating chamber 400.

Also, as illustrated in FIG. 10, the treatment liquid used for substrate treatment in the liquid treating chamber 400 may be directly recovered to a recovery tank 5001, and then flow from the recovery tank 5001 to the supply tank 1200 through the inlet line 1420. In addition, the aqueous solution of phosphoric acid of which the temperature and the concentration are controlled in the supply tank 1200 may be supplied to a buffer tank 5002 through the outlet line 1440, and then the aqueous solution of phosphoric acid may be supplied from the buffer tank 5002 to the nozzle. Any one of the recovery tank 5001 and the buffer tank 5002, or the recovery tank 5001 and the buffer tank 5002 may be provided in the same as or similar structure to that of the supply tank 1200.

In the above-described example, it has been described that the treatment liquid stored in the supply tank 1200 is an aqueous phosphoric acid solution. However, unlike this, the treatment liquid stored in the supply tank 1200 may be another type of treatment liquid including water and of which the concentration is controlled by evaporation of water.

The foregoing detailed description illustrates the present invention. In addition, the above description shows and describes the exemplary embodiments of the present invention, and the present invention may be used in various other combinations, modifications, and environments. That is, changes or modifications are possible within the scope of the concept of the invention disclosed herein, the scope equivalent to the written disclosure, and/or within the scope of skill or knowledge in the art. The foregoing exemplary embodiment describes the best state for implementing the technical spirit of the present invention, and various changes required in specific application fields and uses of the present invention are possible. Accordingly, the detailed description of the invention above is not intended to limit the invention to the disclosed exemplary embodiment. In addition, the appended claims should be construed to include other exemplary embodiments as well.

1. An apparatus for treating a substrate, the apparatus comprising:
a cup providing a treatment space therein;
a support unit for supporting a substrate and rotating the substrate in the treatment space;
a nozzle for supplying a treatment liquid to the substrate; and
a liquid supply unit for supplying the treatment liquid to the nozzle,
wherein the liquid supply unit includes a tank for storing the treatment liquid, and
the tank includes:
a housing having a space for storing the treatment liquid therein;
a circulation line coupled to the housing to circulate the treatment liquid in the housing;
a heater unit installed in the circulation line to heat the treatment liquid; and
a first gas supply line connected to the circulation line to supply first gas into the circulation line.

2. The apparatus of claim 1, wherein the first gas supply line is connected to the circulation line downstream of the heater unit.

3. The apparatus of claim 2, wherein the circulation line includes:
a first line of which a longitudinal direction is provided in a vertical direction;
a second line extending from the first line and connected to the housing so as to be provided upstream from the first line; and
a third line extending from the first line and coupled to the housing so as to be provided downstream of the first line, and
the first gas supply line is connected to the third line.

4. The apparatus of claim 1, wherein the circulation line has an outlet located lower than a liquid level of the treatment liquid in the housing.

5. The apparatus of claim 1, wherein the first gas is supplied to the circulation line in a heated state.

6. The apparatus of claim 5, wherein the first gas is supplied to the circulation line at the same temperature as a temperature of the treatment liquid heated by the heater unit in the circulation line.

7. The apparatus of claim 2, wherein the first gas is supplied to the circulation line at a room temperature state.

8. The apparatus of claim 1, wherein the liquid supply unit further includes a second gas supply line coupled to the housing so as to supply second gas to the housing.

9. The apparatus of claim 8, wherein the second gas supply line is provided to supply the second gas to a position higher than a liquid level of the treatment liquid stored in the housing.

10. The apparatus of claim 9, wherein the second gas is low-humidity gas.

11. The apparatus of claim 1, wherein the treatment liquid includes a chemical liquid and water, and
the heater unit heats the treatment liquid to a temperature higher than a boiling point of water.

12. The apparatus of claim 11, wherein the treatment liquid is an aqueous phosphoric acid solution.

13. An apparatus for treating a substrate, the apparatus comprising:
a cup providing a treatment space therein;
a support unit for supporting a substrate and rotating the substrate in the treatment space;
a nozzle for supplying a treatment liquid to the substrate; and
a liquid supply unit for supplying a treatment liquid of which a concentration and a temperature are controlled to the nozzle,
wherein the treatment liquid includes a chemical liquid and water, and
the liquid supply unit includes:
a housing having a space for storing the treatment liquid therein;
a circulation line coupled to the housing to circulate the treatment liquid in the housing, and including an outlet located lower than a liquid level of the treatment liquid in the housing;
a heater unit installed in the circulation line and for heating the treatment liquid to a temperature higher than a boiling point of the water; and
a gas supply line directly connected to the circulation line to supply gas into the circulation line.

14. The apparatus of claim 13, wherein the gas supply line is connected to the circulation line downstream of the heater unit.

15. The apparatus of claim 13, wherein a heater for heating the first gas is installed in the gas supply line.

16-20. (canceled)
